(19) United States
(12) Patent Application Publication
(10) Pub. No.: US 2023/0059423 A1
(43) Pub. Date: Feb. 23, 2023

(54) MODULE HAVING ELASTIC WAVE DEVICE

(71) Applicant: Sanan Japan Technology Corporation, Tokyo (JP)

(72) Inventors: Hirofumi Nakamura, Tokyo (JP); Koichi Kumagai, Tokyo (JP); Yutaka Kadogawa, Tokyo (JP); Kanehisa Kimbara, Tokyo (JP)

(73) Assignee: Sanan Japan Technology Corporation, Tokyo (JP)

(21) Appl. No.: 17/820,760

(22) Filed: Aug. 18, 2022

(30) Foreign Application Priority Data
Aug. 19, 2021 (JP) 2021-134451

(51) Int. Cl. H03H 9/05; H03H 3/08

(52) U.S. Cl. CPC H03H 9/0576; H03H 3/08

(57) ABSTRACT

A module includes a package substrate, an elastic wave device mounted on the package substrate, the elastic wave device includes a first main surface having a functional element, the first main surface faces the package substrate, a semiconductor device mounted on the package substrate, and a resin made from a single material, the resin covers the elastic wave device while leaving an air gap between the package substrate and the functional element, and the resin covers the semiconductor device while filling a space between the package substrate and the semiconductor device.

### CROSS REFERENCE TO RELATED APPLICATION(S)

This application claims priority to Japanese Patent Application No. 2021-134451 filed Aug. 19, 2021, the disclosure of which is expressly incorporated herein by reference, in its entirety, for any purpose.

### BACKGROUND

### Field

The present disclosure relates to a module having an elastic wave device.

### Background Art

Patent Document 1 (JP2017-157922) discloses a packaging method of an electronic device such as an elastic wave device. This packaging method includes face-down mounting a chip on a circuit board and covering a periphery of the chip with a sealing member.

For example, in Power Amplifier Module integrated Duplexer (PAMiD) formed by mounting components such as a Surface Acoustic Wave (SAW) filter, a power amplifier and a switch on a board, fabricating the module by mounting a bare chip is suitable for miniaturization and thinning the module.

However, it is necessary to place underfill resin under non-SAW chips while leaving a cavity under the SAW filter chip. Therefore, when all the chips are mounted in a bare chip form, different resin sealing methods have to be employed. In other words, a resin for sealing the SAW filter chip and a resin for sealing the other chips must be separately formed, which is unsuitable for lowering the cost.

### SUMMARY

Some examples described herein may address the above-described problems. Some examples described herein may provide a module suitable for low cost.

In some examples, a module includes a package substrate, an elastic wave device mounted on the package substrate, the elastic wave device includes a first main surface having a functional element, the first main surface faces the package substrate, a semiconductor device mounted on the package substrate, and a resin made from a single material, the resin covers the elastic wave device while leaving an air gap between the package substrate and the functional element, and the resin covers the semiconductor device while filling a space between the package substrate and the semiconductor device.

### BRIEF DESCRIPTION OF THE DRAWINGS

FIG. 1 is a cross-sectional view of a module;

FIG. 2 is a flowchart showing a manufacturing method of the module;

FIG. 3 is a diagram showing a device mounted on a substrate;

FIG. 4 shows a device covered with a resin;

FIG. 5 shows a UV exposure for curing a part of the resin;

FIG. 6 shows introducing a resin between the device and the substrate;

FIG. 7A is a photograph of the resin heated after UV irradiation;

FIG. 7B is a photograph of the resin heated without UV irradiation;

FIG. 8 is a diagram showing a through hole of a package substrate;

FIG. 9 shows removing a portion of the resin; and

FIG. 10 is a diagram showing an insulating layer.

### DETAILED DESCRIPTION

Embodiments will be described with reference to the accompanying drawings. In the drawings, the same or corresponding parts are denoted by the same reference numerals. Duplicate descriptions of such portions may be simplified or omitted.

### Embodiment

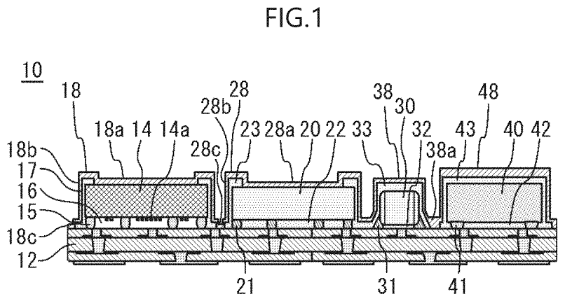

FIG. 1 is a cross-sectional view of a module 10 according to an embodiment. The module 10 comprises a package substrate 12. According to an example, the packaging substrate 12 is a Printed Circuit board (PCB) substrate or a High Temperature Co-fired Ceramics (HTCC) substrate. According to another example, the package substrate 12 is a Low Temperature Co-fired Ceramics (LTCC) multilayer substrate made of a plurality of dielectric layers. According to another example, an arbitrary substrate provided with a base material and wiring electrodes penetrating the base material can be used as the package substrate. In the example of FIG. 1, the package substrate 12 includes a base material, an upper electrode, and a lower electrode electrically connected to the upper electrode by a via wiring or the like. A passive element such as a capacitor or an inductor may be formed within the package substrate 12.

An elastic wave device 14, a semiconductor device 20, a passive element 30 and a semiconductor device 40 are mounted on the package substrate 12 by bumps 15, 21, 31, 41, respectively. The bump 15 electrically connects the package substrate 12 and the elastic wave device 14. The bump 21 electrically connects the package substrate 12 and the semiconductor device 20. The bump 31 electrically connects the package substrate 12 and the passive element 30. The bump 41 electrically connects the package substrate 12 and the semiconductor device 40. The bumps 15, 21, 31, 41 are, for example, gold bumps. According to another example, the bump 31 can be replaced by solder. According to one example, the height of these bumps is between 10 μm and 50 μm.

According to one example, the elastic wave device 14 includes any one of a surface acoustic wave filter, a filter comprising an acoustic thin film resonator, a duplexer, or a dual filter. According to another example, another configuration may be employed as the elastic wave device. The elastic wave device 14 includes a first main surface having a functional element. The elastic wave device 14 is mounted on the package substrate 12 while facing the first main surface to the package substrate 12. In the example of FIG. 1, an Interdigital Transducer (IDT) 14a and a pair of reflectors are provided as the functional element. The IDT 14a and the pair of reflectors are mounted on the first main surface. In one example, a wiring pattern may be formed on the first main surface by an appropriate metal or alloy such as silver, aluminum, copper, titanium, or palladium. The IDT 14a and the pair of reflectors are provided to excite surface acoustic waves. According to another example, as the functional elements, a receiving filter and a transmitting filter are formed on the first main surface. The receiving filter is formed so that an electrical signal in a desired frequency band can pass. For example, the receiving filter is a ladder-type filter consisting of a plurality of series resonators and a plurality of parallel resonators. The transmitting filter is formed so that an electrical signal in a desired frequency band can pass. For example, the transmitting filter is a ladder-type filter consisting of a plurality of series resonators and a plurality of parallel resonators.

The elastic wave device 14 has a substrate formed of, for example, a piezoelectric single crystal such as lithium tantalate, lithium niobate, or quartz. According to another example, the elastic wave device 14 has a substrate formed of piezoelectric ceramics. According to another example, the elastic wave device 14 has a substrate to which a piezoelectric substrate and a support substrate are bonded. For example, the support substrate may be a substrate formed of sapphire, silicon, alumina, spinel, quartz, or glass.

The elastic wave device 14 is covered with a resin 17. However, the first main surface of the elastic wave device 14 is not covered with the resin 17. There is an air gap 16 between the elastic wave device 14 and the package substrate 12. The elastic wave device 14 has a second main surface. The second main surface is a surface opposite to the first main surface. According to an example, at least a portion of the second main surface is not covered with the resin 17. A metal layer 18 is in contact with the second main surface. The metal layer 18 includes a first metal 18a provided on the second main surface, a second metal 18b in contact with the resin 17, and a third metal 18c in contact with the package substrate 12.

According to one example, the semiconductor device 20 includes any one of a power amplifier, a low noise amplifier, or a switch. In the example of FIG. 1, the semiconductor device 20 is a power amplifier. The semiconductor device 20 is covered with resins 22 and 23. The resin 22 is a resin filled between the package substrate 12 and the semiconductor device 20. This resin 22 is provided as an underfill resin. The resin 23 is a resin that covers the side surface and a part of the upper surface of the semiconductor device 20. The semiconductor device 20 has a facing surface and a non-facing surface. The facing surface is a surface facing the package substrate 12. The non-facing surface is a surface opposite to the facing surface. According to one example, at least a portion of the non-facing surface is not covered with a resin. A metal layer 28 is in contact with the non-facing surface. The metal layer 28 includes a first metal 28a provided on the non-facing surface, a second metal 28b in contact with the resin 17, and a third metal 28c in contact with the package substrate 12.

According to one example, the passive element 30 is a capacitor. The passive element 30 is covered with resins 32 and 33. The resin 32 is a resin filled between the package substrate 12 and the passive element 30. Therefore, the resin 32 is provided as an underfill resin. The resin 33 is a resin that covers the side surface and the upper surface of the passive element 30. A metal layer 38 is formed on the resin 33. The metal layer 38 has a first portion 38a in contact with the package substrate 12.

According to one example, the semiconductor device 40 includes any one of a power amplifier, a low noise amplifier, or a switch. In the example of FIG. 1, the semiconductor device 40 is a switch. The semiconductor device 40 is covered with resins 42 and 43. The resin 42 is a resin filled between the package substrate 12 and the semiconductor device 40. The resin 42 is provided as an underfill resin. The resin 43 is a resin that covers the side surface and the upper surface of the semiconductor device 40. A metal layer 48 is formed on the resin 43.

The resin 17 covers the elastic wave device 14 while leaving the air gap 16 between the package substrate 12 and the functional element of the elastic wave device 14. The resins 22 and 23 cover the semiconductor device 20 while filling a space between the package substrate 12 and the semiconductor device 20. The resins 32 and 33 cover the passive element 30 while filling a space between the package substrate 12 and the passive element 30. The resins 42 and 43 cover the semiconductor device 40 while filling a space between the package substrate 12 and the semiconductor device 40.

In one example, all the resins 17, 22, 23, 32, 33, 42, 43 are same material. In other words, the resins 17, 22, 23, 32, 33, 42, 43 has a common composition (molecular structure) both before and after curing by being provided in the same process. According to one example, the resins 17, 22, 23, 32, 33, 42, 43 has a photocuring property and a thermo-curing property. According to one example, the thermo-curing property of the resin is one in which the resin is temporarily softened at a first temperature which is higher than room temperature and is cured by continuing the first temperature or changing the first temperature to a second temperature higher than the first temperature. Various materials may be used as the resin material. According to one example, a material of the resin is any one of the following.
Epoxy-based KPM500 dry films manufactured by Nippon Kayaku
Epoxy-based PSR-800 AUS410, PSR-800 AUS SR1 manufactured by Taiyo Ink
Polyimide-based LPA-22 manufactured by Toray Industries

In the example of FIG. 1, the resin 17 covering the elastic wave device 14 is photo-cured and heat-cured, and the other resins are heat-cured. For example, the resins 22, 42 filled between the package substrate 12 and the semiconductor devices 20, 40 are heat-cured.

As described above, the resins 17, 22, 23, 32, 33, 42, 43 of the module 10 are of the same material. In other words, the resins 17, 22, 23, 32, 33, 42, 43 are made from a single material. Therefore, the material cost can be reduced, and the number of process steps can be reduced as compared with a case wherein different resins are used. Because of this, the module 10 is suitable for low cost. Additionally, the module 10 may be provided as a PAMiD module since the air gap 16 is provided between the package substrate 12 and the elastic wave device 14 and the resins 22, 32, 42 are provided under the chips to serve as underfill resins. Contacting the metal layer 18 with the second main surface of the elastic wave device 14 contributes to improving the heat dissipation. Contacting the metal layer 28 to the non-facing surface of the semiconductor device 20 also contributes to improving the heat dissipation. However, an initial resin may be formed over the entire second main surface of the elastic wave device 14, a metal layer may be formed over the initial resin, a subsequent resin may be formed over the entire non-facing surface of the semiconductor device 20, and a metal layer may be formed over the subsequent resin. The metal layers 18, 28, 38, 48 may also function as electromagnetic shielding layers.

In the example of FIG. 1, the third metal 18c, the third metal 28c, and the first portion 38a are in contact with the package substrate 12. The third metal 18c, the third metal 28c, and the first portion 38a are formed in the opening of the resin directly above the package substrate 12 and are in contact with the package substrate 12. At least one of the third metal 18c, the third metal 28c, and the first portion 38a may be in contact with a conductor pattern of the package substrate 12. The conductor pattern can be the same potential as the ground potential of the elastic wave device 14. Then, the metal layers 18, 28, 38, and 48 can also be set to the ground potential. Grounded metal layers 18, 28, 38, 48 serve as electromagnetic shielding layers.

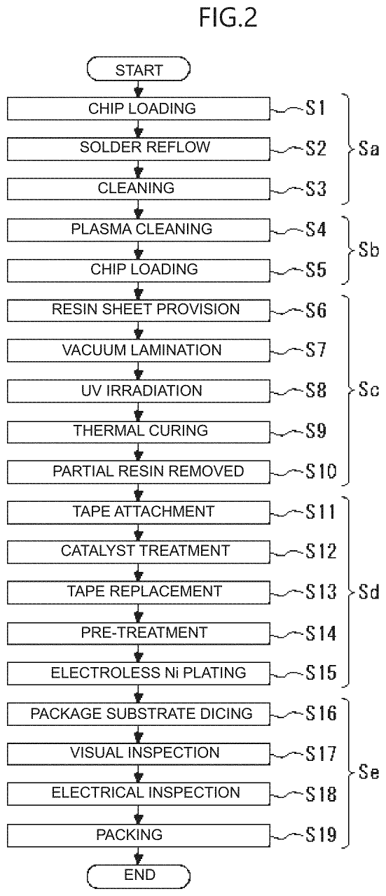

FIG. 2 is a flowchart showing a method of manufacturing a module. A method of manufacturing the module of FIG. 1 will be described with reference to this flowchart. A step “Sa” and a step “Sb” are steps for mounting a plurality of chips on the package substrate 12. The step Sa starts with a step S1. In the step S1, a cream solder is applied to a predetermined position of the package substrate 12. Then, a chip is mounted on the cream solder. Then, after a solder reflow process is conducted in a step S2, a cleaning process is conducted in a step S3. With these processes, the chip is bonded to the package substrate 12.

The step Sb starts with a step S4. In the step S4, the package substrate 12 is subject to a plasma cleaning process. Then, in a step S5, a bump of a chip is bonded to a conductive adhesive provided at a predetermined position of the package substrate 12. According to one example, the step Sb is an Au—Au junction (Gold to Gold Interconnection: GGI) process.

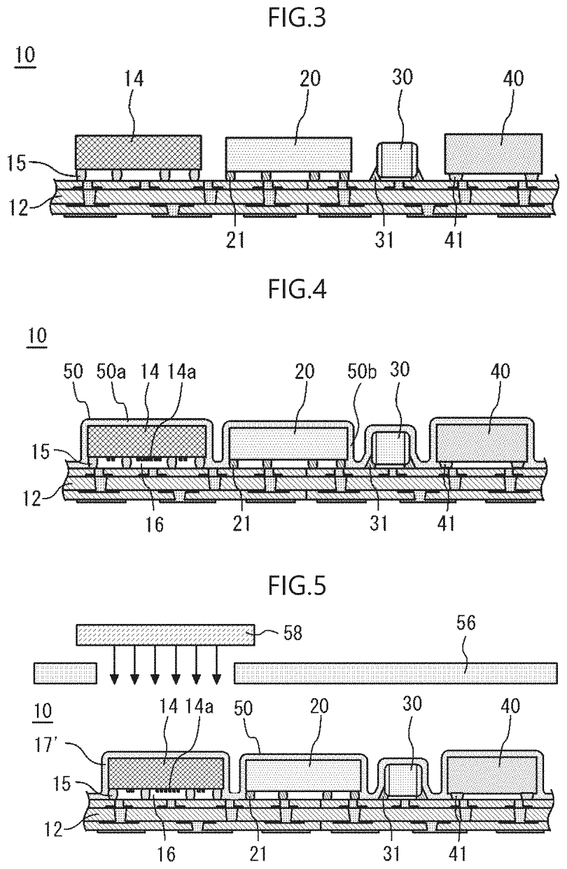

In the step Sa, the chip is mounted on the package substrate using solder, whereas in the step Sb, the chip is mounted on the package substrate using a conductive adhesive. According to one example, the elastic wave device 14 is mounted on the package substrate 12 in the step Sb, and the semiconductor device 20, the passive element 30 and the semiconductor device 40 are mounted on the package substrate 12 in the step Sa. According to another example, the elastic wave device 14 is mounted on the package substrate 12 in the step Sa, and the semiconductor device 20, the passive element 30 and the semiconductor device 40 are mounted on the package substrate 12 in the step Sb. According to still another example, all the chips to be mounted on the package substrate 12 may be mounted in one of the steps Sa and Sb. and the other of the steps Sa and Sb may be omitted. FIG. 3 shows that the elastic wave device 14, the semiconductor devices 20, 40 and the passive element 30 have been mounted on the package substrate 12 by the step Sa and the step Sb. According to one example, the package substrate 12 of FIG. 3 is a substrate in which a unit wiring substrate is arrayed in a two-dimensional direction. In this case, it can be said that a plurality of unit wiring substrates are disposed on the package substrate 12.

Next, the method proceeds to a step Sc. The step Sc is a step of forming a resin. First, in a step S6, a resin sheet is placed so as to cover the plurality of device chips mounted on the package substrate 12. The resin sheet is, for example, a sheet made from a liquid epoxy resin. According to another example, the resin sheet may be a synthetic resin such as polyimide different from an epoxy resin. In one example, a protective film made of polyethylene terephthalate (PET) can be provided on an upper surface of the resin sheet. In one example, a base film made of polyester can be provided on a lower surface of the resin sheet. By placing the resin sheet on the plurality of device chips, the resin sheet is temporarily fixed to the plurality of device chips.

In a step S7, a resin is then provided between the chips by vacuum lamination. According to one example, the resin is provided between the chips by applying pressure to the resin sheet in the direction of the package substrate 12 under vacuum. In one example, a pressure toward the package substrate 12 can be applied to the resin sheet by silicon rubber inflated by compressed air. In another example, a rubber plate can be used to apply pressure to the resin sheet in the direction of the package substrate 12. FIG. 4 is a diagram illustrating a shape example of the resin after vacuum lamination. In FIG. 4, a resin 50 has a portion 50a on the chip and a portion 50b provided between the chips.

Resin may be provided between the chips in a different manner than the vacuum lamination. For example, a method called thermal roller lamination may be employed. In the thermal roller lamination method, by passing a work between an upper roller and a lower roller heated to at least the softening temperature of the resin sheet, the resin sheet is provided on the upper surface of the plurality of device chips, the side surface of the plurality of device chips and the upper surface of the package substrate 12.

Thus, the elastic wave device 14, the semiconductor devices 20 and 40, and the passive element 30 are covered with the resin 50 of a single material. As described above, the resin 50 has the photocuring property and the thermo-curing property.

Then, in a step S8, a portion of the resin covering the elastic wave device 14 is cured. FIG. 5 is a view showing curing a portion of the resin. The resin 50 has a first resin 17′ covering the elastic wave device 14. In the step S8, the first resin 17′ is irradiated with UV rays. According to an example, in this UV irradiation, a mask 56 which has an opening only directly above the first resin 17′ is used. By providing the UV light irradiated from a UV irradiation device 58 to the resin 50 via the mask 56, the first resin 17′ is UV irradiated, and the other portion of the resins 50 (hereinafter, sometimes referred to as a second resin) is not UV irradiated. Thus, only the first resin 17′ of the resin 50 is selectively exposed. By this selective exposure, the first resin 17′ is cured while leaving the air gap 16 between the package substrate 12 and the elastic wave device 14.

The first resin 17′ may be cured by a method other than UV exposure. The first resin 17′ can be cured by various well-known methods other than thermal curing. For example, by irradiating the first resin 17′ with an electron beam, the first resin 17′ may be cured. According to an example, the first resin 17′ can be irradiated with an electron beam by using the mask 56 described above. According to another example, the electron beam emitted from an electron source can be irradiated to the first resin 17′ without the mask by irradiating the electron beam while moving a stage for holding the package substrate. According to another example, electron beam scanning and the mask may be used in combination.

By curing the first resin 17′, the resin maintains the same shape as the resin 17 in FIG. 1 so that the functional element of the elastic wave device 14 is maintained in a state of being exposed to the air gap 16. According to an example, this air gap 16 is an enclosed space.

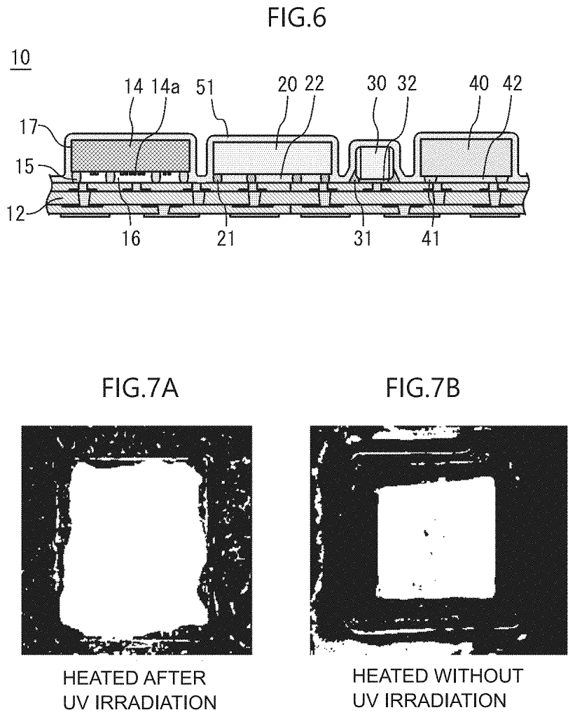

Next, the method proceeds to a step S9. In the step S9, an underfill for the semiconductor device or the like is provided, and then the second resin is thermally cured. Specifically, the second resin that has not been cured in the step S8 is temporarily softened to fill at least a portion of the space between the package substrate 12 and the semiconductor device. In one example, the resin 50 softened by heating flows into the space between a semiconductor devices 20, 40, the passive element 30 and the package substrate 12. FIG. 6 illustrates that the resins 22, 32, 42 functioning as underfill resins are formed by softening a second resin 51.

Once the underfill resins are thus provided, the second resin 51 is thermally cured. The method of thermo-curing on the material of the resin. For example, the second resin may be cured by continuing the first temperature, which is a temperature at which the second resin is softened, for a certain period of time. In another resin, the second resin may be cured by the second temperature higher than the first temperature. With such a heat treatment for softening and curing of the second resin, curing of the first resin 17′ is also accelerated. In other words, the first resin 17′ is cured to such an extent that the shape is substantially fixed by the aforementioned exposure treatment, and is completely cured by the subsequent heat treatment of the second resin. Specifically, the first resin 17′ is thermally cured by the heat treatment. Fluidization of the first resin 17′ by the heat treatment is avoided or suppressed so that the resin does not cover the IDT 14a.

In one example, the process of softening and curing the resin proceeds by pressing the resin sheet in the direction of the package substrate 12 by a press machine having a heated upper die and a lower die. For example, the resin sheet is heated to a softening temperature to form an underfill, and then further heated to a curing temperature to fix the shape.

By using a resin having the photocuring property and the thermo-curing property, the above-described process becomes possible. FIG. 7 is an experimental result showing that the fluidity of the resin at the time of heating can be controlled by the presence or absence of UV irradiation. In this experiment, a cover glass having a thickness of about 150 μm in 5 mm square was provided on a slide glass substrate with a spacer having a thickness of about 20 μm interposed therebetween. The cover glass has a larger area than the spacer. Then, a dry film resin was placed on the cover glass at a lamination temperature of about 60° C. Two samples with this configuration were prepared, one resin was UV irradiated, and the other resin was not UV irradiated. Subsequently, these two samples were heated at 180° C. for 1 min. FIG. 7A is a photograph showing that the flow of the resin was suppressed in the UV-irradiated sample. Dark portions are resins. It can be seen from FIG. 7A that although the resin slightly flowed in the vicinity of the square cover glass, the flow of the resin was substantially suppressed. On the other hand, FIG. 7B is a photograph showing that the samples without UV-irradiation fail to suppress the resin flow. Dark portions are resins. From FIG. 7B, it can be seen that many resins flowed directly under the substantially square cover glass.

Incidentally, when air is present in the space between the chip and the package substrate 12 when the resin is thermally cured, filling of the space with underfill can be inhibited.

In order to avoid or to reduce this problem, an underfill resin may be provided to a space between the package substrate 12 and the semiconductor devices 20 and 40 before covering the chips including the elastic wave device 14 and the semiconductor devices 20 and 40 with the resin, For example, an underfill resin having thermo-curing properties may be provided between the package substrate 12 and the semiconductor device 20, between the package substrate 12 and the passive element 30, and between the package substrate 12 and the semiconductor device 40. Then the underfill resin and the second resin can be softened simultaneously. Thus, the space between the package substrate 12 and the chip can be filled with resin.

According to another example, the step of covering the elastic wave device 14 and the semiconductor device with resin, the step of curing the first resin 17′, and the step of softening the second resin 51 are performed in a vacuum space. By this vacuum space, an underfill can be provided in a state where there is no air between the chip and the package substrate 12. This ensures filling of the underfill.

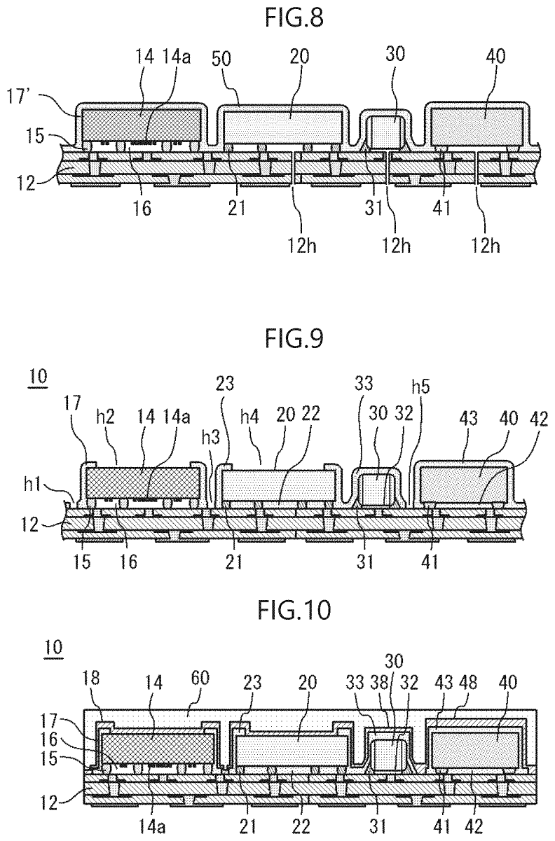

According to still another example, a through hole of the package substrate 12 can be provided immediately below the chip on which the underfill is to be provided. For example, a through hole of the package substrate 12 is formed immediately below the semiconductor device. FIG. 8 is a view showing a through hole 12h formed in the package substrate 12. When the underfill is formed by flowing the resin, the air between the package substrate 12 and the chip escapes below the package substrate 12 through the through hole 12h, whereby filling of the underfill can be ensured.

The above-mentioned techniques including provision of the underfill resin, the utilization of vacuum, and the formation of the through-hole can be used in combination. For example, when the underfill resin and the second resin flow, the air between the package substrate 12 and the chip can be discharged from the through hole of the package substrate 12. The provision of underfill resins, the utilization of vacuum, and the formation of the through-hole can be supplementarily provided to fully perform the underfill. Therefore, these methods can be omitted.

Next, the method proceeds to a step S10. In the step S10, a part of the resin is removed. FIG. 9 is a diagram illustrating an example of removal of the resin. In this example, an opening h2 is formed by removing at least a part of the resin formed on the elastic wave device 14, and an opening h4 is formed by removing at least a part of the resin formed on the semiconductor device 20. Furthermore, openings h1, h3, h5 for exposing the package substrate 12 are formed. In this example, at least a part of the resin formed on the semiconductor device 20 which is the power amplifier is removed, and the resin formed on the semiconductor device 40 which is the switch is not removed. According to one example, the resin is removed using laser light.

Next, the method proceeds to a step Sd. The step Sd is a step of forming a metal layer.

For example, in a step S11, a tape is attached to the back surface of the package substrate 12. Subsequently, in a step S12, a catalyst treatment for causing an electroless plating reaction is performed. Then, the tape is replaced in a step 13, a pretreatment is performed in a step S14, an electroless Ni plating is formed in a step S15. Thus, the metal layer covering the resin is formed by plating. Specifically, the metal layers 18, 28, 38, 48 of FIG. 1 are formed. According to one example, the metal layer is filled in the opening of the resin and contacts the conductor pattern of the package substrate 12. The metal layers 18, 28, 38, 48 may be formed by a method other than electroless Ni plating. According to one example, in order to form the metal layer, an electroless Cu plating and a electroless Ni plating are conducted in this order. According to another example, a silver coating and an electroless Ni plating are conducted in this order to form the metal layer. According to yet another example, Ti formation, Cu sputtering, electrolytic Ni plating are conducted in this order to form the metal layer. In these modified examples, the adhesiveness between the resin and the metal layer can be enhanced as compared with the case where the metal layer is formed by electroless Ni plating.

Next, the method proceeds to a step Se. The step Se is a so-called post-process. For example, in a step S16, the package substrate 12 is diced. As a result, the product is singulated. Next, the appearance is visually inspected in a step S17, and the electrical characteristics of the product are inspected in a step S18. If there is no problem, the product is packed in a step S19. Thus, the manufacture of the module 10 shown in FIG. 1 is completed.

According to an example, it is possible to form an insulating layer on the upper surface of the module of FIG. 1. FIG. 10 shows an insulating layer 60. In this example, a step of forming an insulating layer 60 on the metal layers 18, 28, 38, 48 is added. According to one example, the upper surface of the insulating layer 60 is substantially flat.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners.

Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

1. A module, comprising:
a package substrate;
an elastic wave device mounted on the package substrate, the elastic wave device includes a first main surface having a functional element, the first main surface faces the package substrate;
a semiconductor device mounted on the package substrate; and
a resin made from a single material, the resin comprising a first resin and a second resin, the first resin covers the elastic wave device while leaving an air gap between the package substrate and the functional element, and the second resin covers the semiconductor device while filling a space between the package substrate and the semiconductor device.

2. The module according to claim 1, wherein the resin has a photocuring property and a thermo-curing property.

3. The module according to claim 1, wherein the first resin covering the elastic wave device is photo-cured and heat-cured, and the second resin filled between the package substrate and the semiconductor devices is heat-cured.

4. The module according to claim 1, wherein the elastic wave device includes a second main surface opposite to the first main surface, and at least a portion of the second main surface is not covered with the first resin.

5. The module according to claim 1, wherein
the semiconductor device has a facing surface and a non-facing surface;
the facing surface is a surface facing the package substrate;
the non-facing surface is a surface opposite to the facing surface; and
at least a portion of the non-facing surface is not covered with the resin.

6. The module according to claim 1, wherein the elastic wave device includes any one of a surface acoustic wave filter, a filter comprising an acoustic thin film resonator, a duplexer, and a dual filter.

7. The module according to claim 1, wherein the semiconductor device includes any one of a power amplifier, a low noise amplifier, and a switch.

8. The module according to claim 1, wherein
the semiconductor device includes a power amplifier and a switch;
at least a portion of an upper surface of the power amplifier is not covered with the resin; and
an upper surface of the switch is covered with the resin.

9. The module according to claim 2, wherein the thermo-curing property of the resin is one in which the resin is temporarily softened at a first temperature which is higher than room temperature and is cured by continuing the first temperature or changing the first temperature to a second temperature higher than the first temperature.

10. The module according to claim 4, comprising a metal layer covering the first resin, the metal layer is in contact with the second main surface.

11. The module according to claim 5, comprising a metal layer covering the second resin, the metal layer is in contact with the non-facing surface.

12. The module according to claim 10, wherein
the resin has an opening directly above the package substrate; and
the metal layer is in contact with a conductor pattern of the package substrate by being formed in the opening.

13. The module according to claim 12, wherein electrical potential of the conductor pattern is a ground potential of the elastic wave device.

14. The module according to claim 10, comprising an insulating layer on the metal layer, an upper surface of the insulating layer is substantially flat.
